(19) United States
(12) Patent Application Publication
(10) Pub. No.: US 2026/0088762 A1
(43) Pub. Date: Mar. 26, 2026

(54) DIGITAL ENVELOPE DETECTOR CIRCUIT, CORRESPONDING SYSTEM-ON-CHIP AND METHOD OF OPERATION

(71) Applicant: STMicroelectronics International N.V., Geneva (CH)

(72) Inventor: Kevin Luciani, Torino (IT)

(21) Appl. No.: 19/325,108

(22) Filed: Sep. 10, 2025

(30) Foreign Application Priority Data
Sep. 25, 2024 (IT) 102024000021302

(51) Int. Cl. H03D 1/22; G01R 29/08

(52) U.S. Cl. CPC H03D 1/2209; G01R 29/0892; H03D 2200/005; H03D 2200/0054; H03D 2200/0086

(57) ABSTRACT

In a digital envelope detector circuit, an input terminal receives a digital input signal and an output terminal produces a digital output signal. First and second digital processing circuitry between the input and output terminals each includes a memory element. The first processing circuitry applies low-pass filtering to the digital input signal. The second processing circuitry processes the digital input signal, stores in the memory element a value indicative of the processed digital input signal, and processes the output from the memory element so that the digital input signal is passed unaltered. A digital comparator circuit compares the digital input and output signals, asserts a control signal in response to the digital input signal being higher, and de-asserts the control signal in response to the digital input signal being lower. The first/second processing circuitry produces the digital output signal in response to the control signal being de-asserted/asserted.

### CROSS-REFERENCED TO RELATED APPLICATIONS

This application claims the priority benefit of Italian Patent Application No. 102024000021302, filed on Sep. 25, 2024 entitled “Digital Envelope Detector Circuit, Corresponding System-On-Chip and Method of Operation,” which is hereby incorporated herein by reference to the maximum extent allowable by law.

### TECHNICAL FIELD

The description relates to digital envelope detector circuits, which can be used for demodulating signals modulated with an Amplitude-Shift Keying (ASK) modulation.

### BACKGROUND

In the field of inductive wireless power transmission, ASK modulation may be used for exchanging data between a power transmitter device PTx (i.e., the charger device) and a power receiver device PRx (i.e., usually a portable electronic device such as a mobile phone, tablet, or the like).

FIG. 1 is a diagram exemplary of a wireless power transmission system, which includes a charging pad 10 that receives electrical energy from the power mains via a power cable 12, and a portable electronic device 14 (e.g., a smart phone) that includes a battery that can be inductively charged by the charging pad 10. To this effect, the charging pad 10 includes a power-transmitting coil 10a, and the device 14 includes a power-receiving coil 14a (both coils 10a and 14a being depicted in FIG. 1 as separate elements from the pad 10 and the device 14 just for the sake of explanation), which are configured to be inductively coupled when the portable device 14 is laid on the charging pad 10. The power transmitter 10 generates an alternating current (AC) in the power-transmitting coil 10a to induce a time-varying magnetic field through the power-receiving coil 14a. Some standards for wireless power transfer, such as the Qi standard, use a communication protocol to exchange data between the devices 10 and 14 to manage the charging process: further details on the Qi standard for wireless charging systems can be found in the Qi specification documents, version 1.3 of January 2021, publicly available at www.wirelesspowerconsortium.com. Substantially, in such communication protocols such as Qi, the power transmitter 10 can send messages to the power receiver 14 exploiting Frequency-Shift Keying (FSK) modulation, and the power receiver 14 can respond to the power transmitter 10 exploiting Amplitude-Shift Keying (ASK) modulation.

FIG. 2 is a circuit diagram exemplary of some internal components of the devices 10 and 14 used for wireless power transmission. Substantially, the power transmitter 10 includes the coil 10a and an AC power source (e.g., a sinusoidal current generator) that supplies the coil 10a, for instance via a series RC circuit (resistor-capacitor). The power receiver 14 includes the coil 14a inductively coupled with the coil 10a, a switchable capacitive network arranged downstream of the coil 14a, a bridge rectifier circuit (e.g., a diode bridge) arranged downstream of the switchable capacitive network, a parallel RC circuit arranged at the output of the rectifier circuit, and a switchable load (e.g., a resistor in series with an electronic switch) selectively couplable in parallel to the RC circuit. The voltage at the power-transmitting coil 10a is a sinusoidal wave W that carries the power to be transmitted to the power-receiving coil 14a. The power receiver device 14 is able to slightly change (modulate) the amplitude of the power carrier wave by changing its internal load impedance (e.g., by selectively coupling and decoupling the switchable load to and from the RC circuit), and this mechanism is used to implement ASK modulation of the carrier wave to transmit information from the power receiver to the power transmitter side. The power transmitter device 10 can sense the voltage across the coil 10a and demodulate the message sent by the power receiver device 14, thus implementing ASK demodulation. The demodulation logic can be fully digital, using an analog-to-digital converter (ADC) to monitor the voltage at coil 10a.

In particular, the Qi protocol may rely on a Manchester-like ASK encoding as exemplified in FIG. 3, which shows the waveforms of a clock signal CLK with period t_{CLK} and a data signal DATA (obtained after ASK demodulation of the sinusoidal carrier wave). Substantially, the digital signal DATA is interpreted as carrying a ‘0’ bit if its value is constant (either high or low) during an entire clock cycle, while it is interpreted as carrying a ‘1’ bit if its value changes during a clock cycle (either a rising edge or a falling edge).

The waveforms of an input modulated signal Wand an output demodulated signal DATA of an ASK demodulator are again shown in FIG. 4. The modulated signal Wis assumed to be sampled by an ADC, so that the entire demodulation process can be carried out using digital hardware (e.g., inside the power transmitting device 10).

A known solution for demodulating an ASK-modulated signal is in-phase quadrature-phase (IQ) demodulation. An IQ demodulator 50 according to the prior art is depicted in the circuit block diagram of FIG. 5. The IQ demodulator 50 includes an ADC 51 that samples an analog modulated signal (e.g., signal W) and produces a corresponding digital signal x[n]. Signal x[n] is passed to a band-pass filter (BPF) 52 to remove out-of-band noise and maintain the modulated signal only. A local oscillator 53 produces a local sinusoidal carrier wave at frequency Fe, e.g., a cosine wave cos(wot). A phase shifter 54 shifts the cosine wave cos(wot) by 90° to produce a sine wave sin(wot). A multiplier 55a multiplies the filtered signal x[n] by the cosine wave cos(wot), and a multiplier 55b multiplies the filtered signal x[n] by the sine wave sin(wot). Low-pass filters (LPF) 56a and 56b, coupled respectively to multipliers 55a and 55b, remove the components around frequency 2·Fc from the respective input signals. High-pass filters (HPF) 57a and 57b, coupled respectively to filters 56a and 56b, remove the DC component from the respective input signals, and produce respective output signals i[n] and q[n].

Solutions based on IQ demodulation as exemplified in FIG. 5 are disadvantageous insofar as they involve a high silicon area, due to the implementation of the phase shifter 54 (which can be done either via a look-up table or using a hardware implementation of a CORDIC algorithm), the implementation of multipliers 55a and 55b, and the implementation of filters 56a, 56b, 57a and 57b using FIR/IIR structures.

Another known solution for demodulating an ASK-modulated signal relies on rectification and low-pass filtering of the ASK-modulated signal. A demodulator 60 according to the prior art is depicted in the circuit block diagram of FIG. 6, and corresponding signal waveforms are depicted in FIG. 7. The demodulator 60 includes an ADC 61 that samples an analog modulated signal (e.g., signal W) and produces a corresponding digital signal x[n]. Signal x[n] is passed to a band-pass filter (BPF) 62 that eliminates the DC component and out-of-band noise. The output of the BPF 62 (e.g., signal out₆₂ in FIG. 7) is rectified by a digital rectifier 63 (e.g., if the output of filter 62 is represented in two's complement, digital rectification is carried out by an absolute value block that inverts the sign of negative values). The output of the digital rectifier 63 (e.g., signal out₆₃ in FIG. 7) is passed to a low-pass filter (LPF) 64 that follows the envelope of the output from rectifier 63 (e.g., using a finite impulse response—FIR—or infinite impulse response—IIR—low-pass filter). The output of the low-pass filter 64 (e.g., signal out₆₄ in FIG. 7) is passed to a high-pass filter (HPF) 65 that removes the DC component of the envelope and produces the output signal q[n].

Solutions based on rectification and low-pass filtering as exemplified in FIGS. 6 and 7 are disadvantageous insofar as they also involve a high silicon area, due to the implementation of filters 62, 64 and 65 and the implementation of the digital rectifier 63. A document possibly of interest in this field is US 2021/0358464 A1. This document discloses a dual peak detector implemented digitally, which receives a digitized input signal from an ADC (analog-to-digital converter). The peak value is stored in a memory and this peak value is compared with the digitized input on every cycle. If the value of the digitized input is greater than the currently stored peak value, a multiplexer selects the digitized input on the next cycle and it gets stored as the peak value for that cycle. If the digitized input is less than the currently stored peak value, either the peak value is held or, if an appropriate number of cycles has elapsed and the value of a signal “decay” is 1, an attenuated version “a*peak” is stored as the next peak value, where a is less than 1 and determines the time constant of decay.

Other documents possibly of interest include KR 2011/0080890 A, US 2006/0074607 A1, US 2016/0236637 A1, U.S. Pat. No. 11,329,634 B1, and the article by Kennedy H. L., “Digital filter designs for recursive frequency analysis”, Journal of Circuits, Systems and Computers, 25(02), 2016, 1630001, doi: 10.48550/arXiv.1408.2294.

Therefore, there is a need in the art to provide improved digital envelope detector circuits, which can be used as demodulators for ASK-modulated signals and occupy less silicon area than the known solutions.

### SUMMARY

An object of one or more embodiments is to contribute in providing such improved digital envelope detector circuits, and corresponding system-on-chips and methods of operation.

According to one or more embodiments, such an object can be achieved by a digital envelope detector circuit having the features set forth in the claims that follow.

One or more embodiments may relate to a corresponding system-on-chip (SoC).

One or more embodiments may relate to a corresponding method of operation.

The claims are an integral part of the technical teaching provided herein in respect of the embodiments.

According to an aspect of the present description, a digital envelope detector circuit includes an input terminal configured to receive a digital input signal and an output terminal configured to produce a digital output signal. The envelope detector includes a memory element, first digital processing circuitry arranged between the input terminal and the output terminal and including the memory element, and second digital processing circuitry arranged between the input terminal and the output terminal and including the memory element. The first digital processing circuitry is configured to apply low-pass filtering to the digital input signal. The second digital processing circuitry is configured to process the digital input signal, store in the memory element a value indicative of the processed digital input signal, and process the output from the memory element so that the digital input signal is passed unaltered to the output terminal. The envelope detector includes a digital comparator circuit configured to compare the digital input signal to the digital output signal, assert a control signal in response to the digital input signal being higher than the digital output signal, and de-assert the control signal in response to the digital input signal being lower than the digital output signal. The first digital processing circuitry is enabled to produce the digital output signal in response to the control signal being de-asserted, and the second digital processing circuitry is enabled to produce the digital output signal in response to the control signal being asserted.

One or more embodiments may thus provide a digital envelope detector circuit with low silicon area footprint.

According to another aspect of the present description, a system-on-chip (e.g., a controller for a wireless power transmitter) includes an analog-to-digital converter (ADC), a digital envelope detector circuit according to one or more embodiments, and an ASK demodulator circuit. The ADC is configured to receive an analog amplitude-modulated signal and convert it to produce a digital input signal for the digital envelope detector circuit. The digital envelope detector circuit is configured to receive the digital input signal from the ADC and produce a digital output signal. The ASK demodulator circuit is configured to decode the digital output signal produced by the digital envelope detector circuit.

According to another aspect of the present description, a method of operating a digital envelope detector circuit according to one or more embodiments or a system-on-chip according to one or more embodiments includes:
receiving a digital input signal at the input terminal;
applying low-pass filtering to the digital input signal by the first digital processing circuitry;
processing the digital input signal, storing in the memory element a value indicative of the processed digital input signal, and processing the output from the memory element so that the digital input signal is passed unaltered by the second digital processing circuitry to the output terminal;
comparing the digital input signal to the digital output signal, asserting a control signal in response to the digital input signal being higher than the digital output signal, and de-asserting the control signal in response to the digital input signal being lower than the digital output signal, by the digital comparator circuit;
enabling the first digital processing circuitry to produce the digital output signal in response to the control signal being de-asserted;
enabling the second digital processing circuitry to produce the digital output signal in response to the control signal being asserted; and
producing the digital output signal at the output terminal.

### BRIEF DESCRIPTION OF THE DRAWINGS

One or more embodiments will now be described, by way of example only, with reference to the annexed figures, wherein:

FIG. 1, previously presented, is a diagram exemplary of a wireless power transmission system;

FIG. 2, previously presented, is a circuit diagram exemplary of some components of the devices of the wireless power transmission system of FIG. 1;

FIGS. 3 and 4, previously presented, are time diagrams including waveforms of signals in an ASK demodulator circuit;

FIG. 5, previously presented, is a circuit block diagram exemplary of an IQ demodulator circuit according to the prior art;

FIG. 6, previously presented, is a circuit block diagram exemplary of another ASK demodulator circuit according to the prior art;

FIG. 7, previously presented, is a time diagram including waveforms of signals in the ASK demodulator circuit of FIG. 6;

FIG. 8 is a circuit diagram exemplary of a conventional analog envelope detector circuit;

FIG. 9 is a time diagram including exemplary waveforms of signals in the envelope detector circuit of FIG. 8;

FIG. 10 is a circuit block diagram exemplary of a digital IIR DC-track filter;

FIG. 11 is a diagram exemplary of the magnitude of the transfer function of the digital IIR DC-track filter of FIG. 10;

FIG. 12 is a circuit block diagram exemplary of a digital envelope detector circuit according to one or more embodiments of the present description; and

FIG. 13 is a circuit block diagram exemplary of a digital envelope detector circuit followed by a DC remover circuit according to one or more embodiments of the present description, in particular according to a folded architecture.

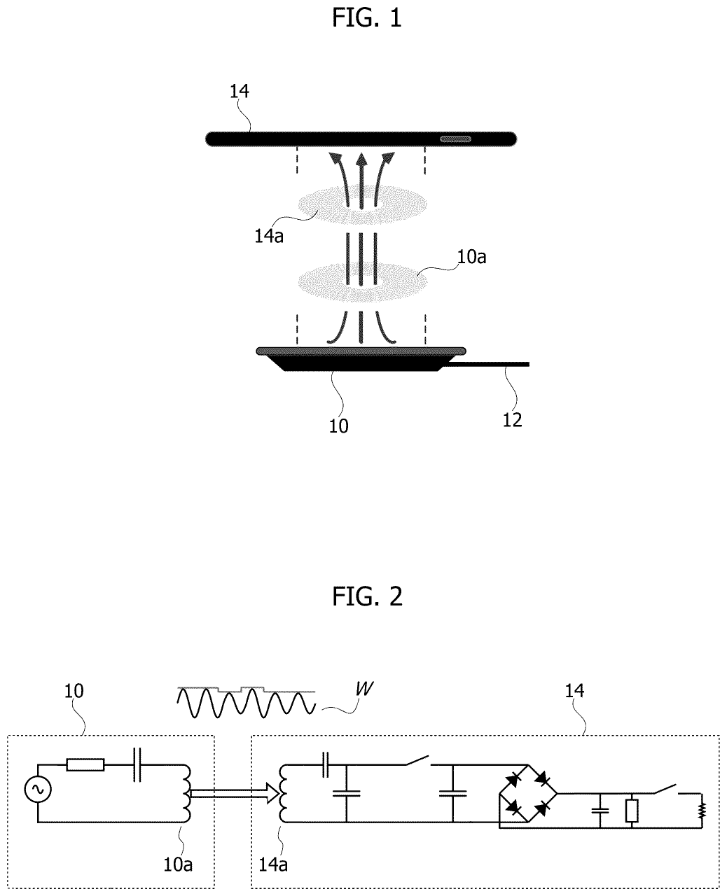

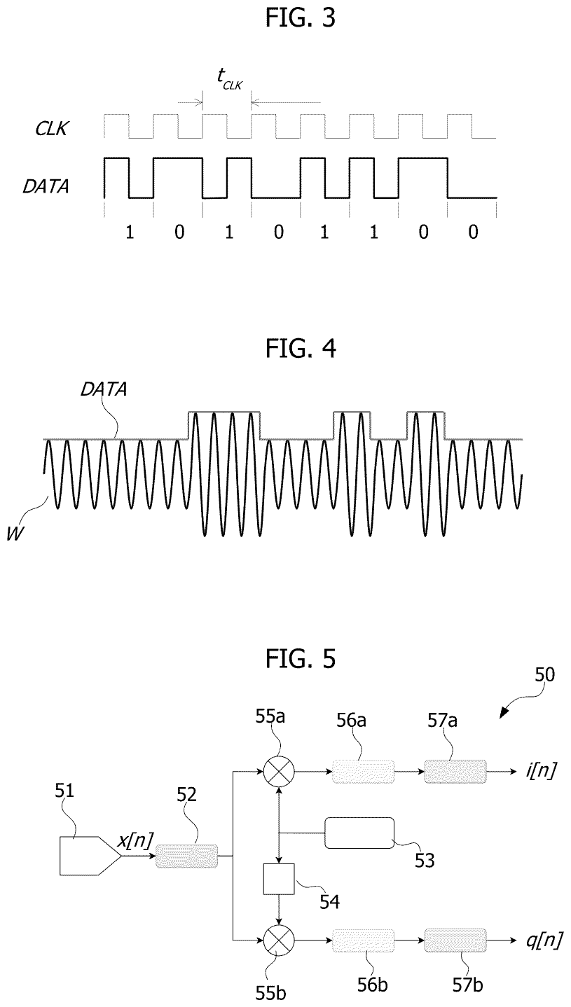

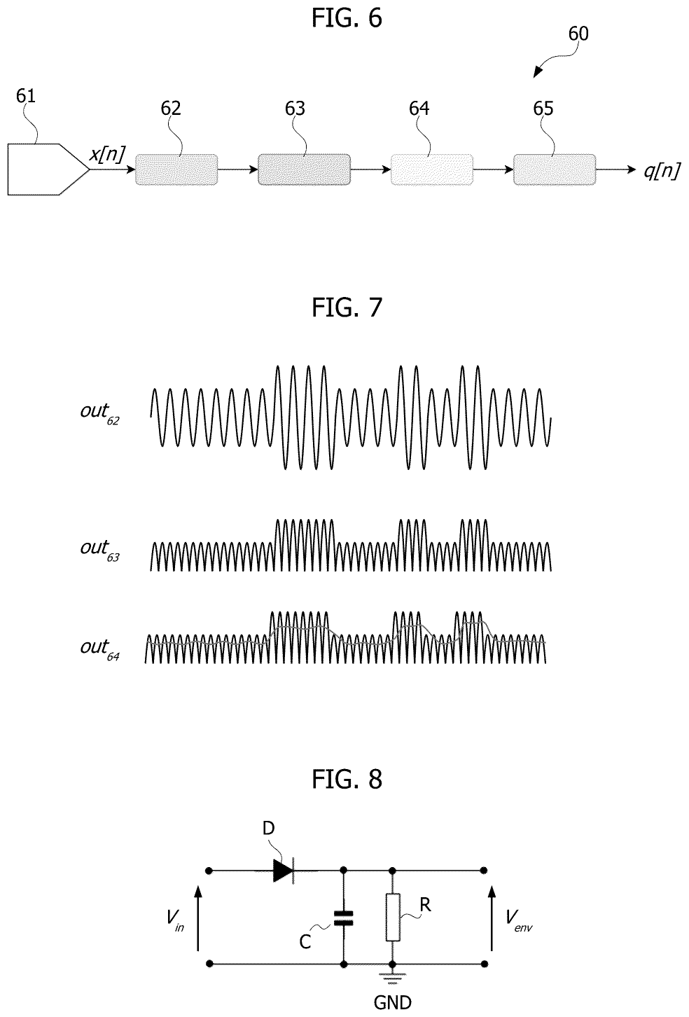

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

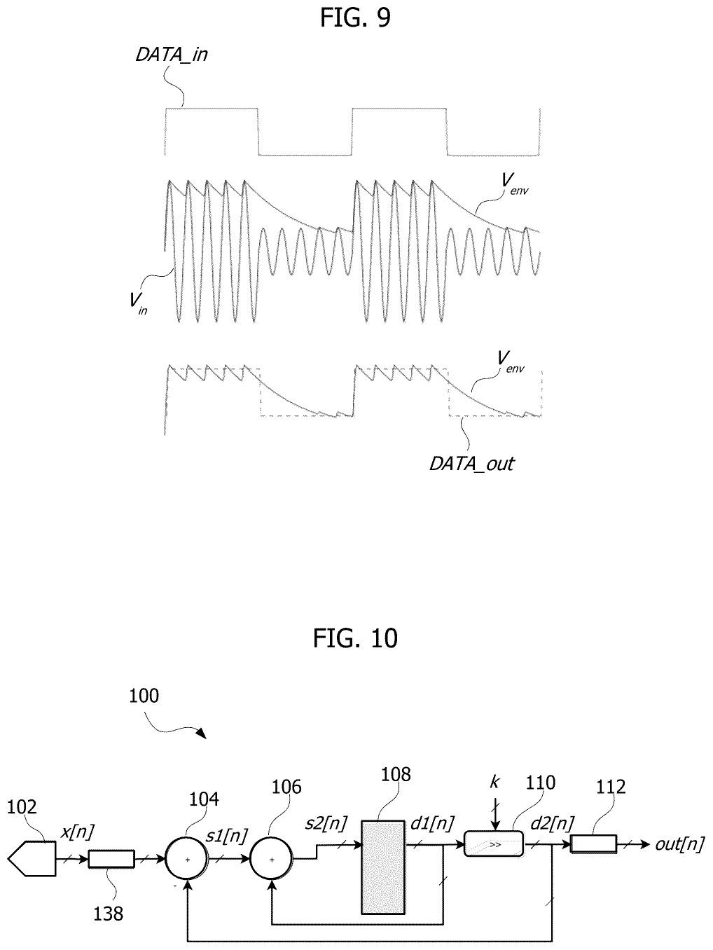

As anticipated, the present description relates to a digital envelope detector circuit that aims at mitigating one or more of the drawbacks that the conventional ASK demodulator circuits have, in particular in order to facilitate the implementation of a digital ASK demodulator with a smaller silicon footprint. The concept of one or more embodiments is that of replicating, with a digital circuit, the behavior of a known analog envelope detector circuit, which is conventionally used for demodulating amplitude-modulated signals. In this respect, by way of introduction to the detailed description of exemplary embodiments, reference may be made to FIG. 8, which is a circuit diagram exemplary of a conventional analog envelope detector circuit, and FIG. 9, which is a time diagram including exemplary waveforms of signals in the envelope detector of FIG. 8. As exemplified in FIG. 8, an analog envelope detector includes a pair of input terminals for receiving an input analog voltage signal Vᵢₙ, and a pair of output terminals to produce an output analog envelope voltage signal Vₑₙᵥ. The (conventionally) negative input terminal and the (conventionally) negative output terminal are connected to ground GND. A diode D has an anode terminal connected to the (conventionally) positive input terminal and a cathode terminal connected to the (conventionally) positive output terminal. A capacitor C and a resistor R are coupled in parallel to each other, between the positive output terminal and ground. With this arrangement, the analog envelope detector operates as exemplified by the waveforms of FIG. 9. In particular, the digital signal DATA_in is the modulating signal that modulates the sinusoidal carrier wave, to produce the modulated signal Vᵢₙ. The output voltage Vₑₙᵥ of the envelope detector tracks (e.g., follows) the input voltage Vᵢₙ when the input voltage increases, and instead decays exponentially (with a time constant dictated by the capacitance and resistance values of the capacitor C and resistor R) when the input voltage decreases. The digital output signal DATA_out may be generated by comparing the envelope signal Vₑₙᵥ to one or more thresholds.

In order to replicate such behavior with a digital circuit, one or more embodiments may rely on the implementation of a low-area digital filter circuit that can be referred to as “IIR DC-track filter”. The architecture of a digital IIR DC-track filter 100 is reproduced in the circuit block diagram of FIG. 10. The filter 100 receives an input digital signal x[n](e.g., a 12-bit signal) from an ADC 102 (which may be considered to be a part of the filter 100 itself, or not). Possibly, the input signal x[n] may be passed to a sign extension circuit 138, which increases its number of bits (e.g., from 12 bits to 26 bits). The filter 100 includes a subtractor circuit 104 that subtracts a feedback signal d2[n](e.g., a 26-bit signal) coming from an output stage of the filter 100 from the signal x[n] to produce a first intermediate signal s1[n](e.g., a 26-bit signal). The filter 100 includes an adder circuit 106 that adds together the intermediate signal s1[n] and another feedback signal d1[n](e.g., a 26-bit signal) coming from another output stage of the filter 100 to produce a second intermediate signal s2[n](e.g., a 26-bit signal). The filter 100 includes a memory element 108 (e.g., a flip-flop, FF) that receives the second intermediate signal s2[n], stores the value of signal s2[n] and passes it to its output as directed by a clock signal or enable signal of the filter circuit 100 (not visible in FIG. 10 for the sake of ease of illustration). The output of the memory element 108 corresponds to the feedback signal d1[n] that is passed to the adder circuit 106. The filter 100 includes a right-shifter circuit 110 that receives signal d1[n] from the memory element 108 and a shift-control signal k (e.g., a 4-bit signal), and produces the signal d2[n] by right-shifting signal d1[n] by an amount of bits as dictated by the decimal value of signal k. For instance, if signal k is a 4-bit signal, it can assume values in the range [0; 15], and the shifter circuit 110 can thus right-shift signal d1[n] by a minimum of 0 bits (i.e., no shifting) to a maximum of 15 bits. Substantially, operation of the shifter circuit 110 corresponds to dividing the decimal value of signal d1[n] by a quantity equal to 2^{k} to compute the decimal value of signal d2[n]. Optionally, the filter 100 includes a truncation circuit 112 that receives signal d2[n] and truncates it (e.g., discarding one or more bits starting from the least significant bit, LSB) to reduce its number of bits and produce the filter output signal out[n](e.g., passing from a 26-bit signal to a 12-bit signal). Therefore, the transfer function of the digital IIR DC-track filter 100 can be written as follows:

$$H ( z ) = \frac{{2}^{- k} {z}^{- 1}}{1 - ( 1 - {2}^{- k} ) {z}^{- 1}} \\ k ∈ [ 0 ; 15 ]$$

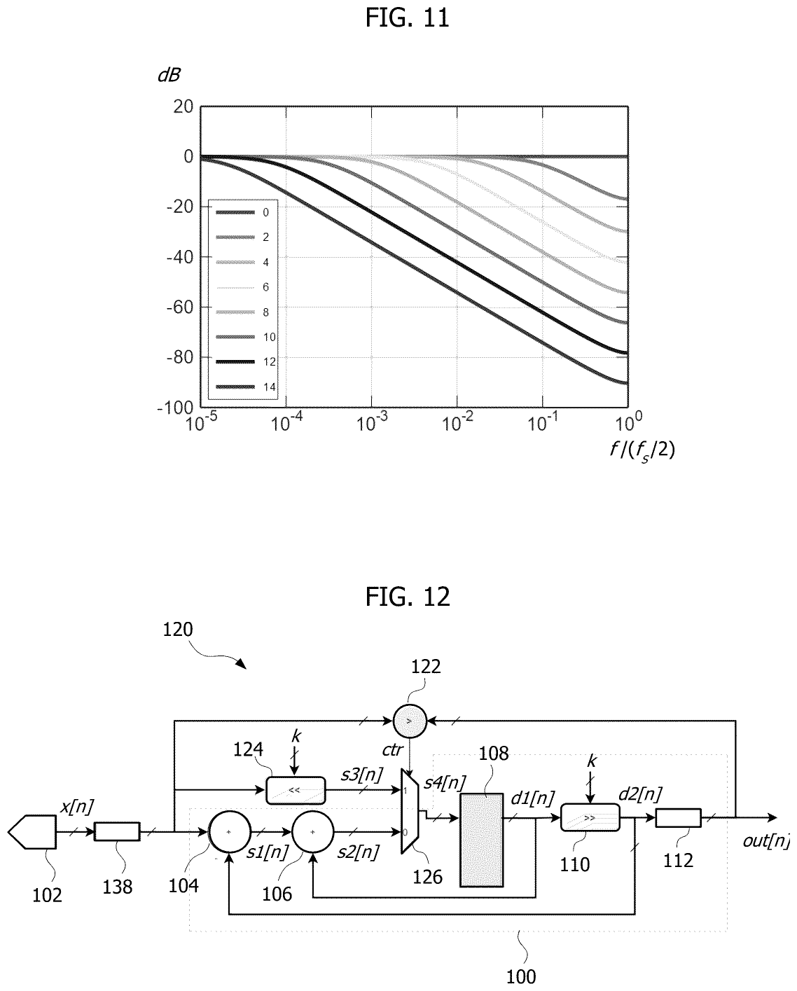

Substantially, the filter 100 implements an IIR (Infinite Impulse Response) structure that is based (only) on shift operations and addition/subtraction operations, hence it is very area efficient. The filter 100 can generate low-pass responses with a cutoff frequency that decreases as the value of signal k increases. In this respect, reference may be made to the diagram of FIG. 11, which shows the magnitude (in dB) of the transfer function of the filter 100 as a function of the normalized frequency f/(fₛ/2) (in absolute value) for different values of k, ranging from 0 to 14. The cutoff frequency can reach very low values; hence, this filter can be employed for computing the DC value of the input signal.

In order to emulate the behavior of an analog envelope detector using a digital DC-track filter 100 as exemplified in FIG. 10, one or more embodiments rely on the approach of constantly comparing the input signal x[n] to the output signal out[n], and forcing the internal value of the memory element 108 depending on the result of such comparison, as exemplified in the circuit block diagram of FIG. 12, which illustrates the structure of a digital envelope detector 120 according to one or more embodiments. The envelope detector 120 includes a DC-track filter 100, and a (digital) comparator circuit 122 that compares the value of the input signal x[n] to the value of the output signal out[n]. If the input signal x[n] is greater than the output signal out[n], the comparator 122 asserts (e.g., sets to ‘1’, logic high) a control signal ctr. If the input signal x[n] is lower than the output signal out[n], the comparator 122 de-asserts (e.g., sets to ‘0’, logic low) the control signal ctr. The case where the input signal x[n] is equal to the output signal out[n] can be indifferently associated to the assertion or de-assertion of the control signal ctr, in different embodiments. The envelope detector 120 includes a left-shifter circuit 124 that receives the input signal x[n] and the same shift-control signal k that controls the right-shifter circuit 110 of the filter 100, and produces an intermediate signal s3[n] by left-shifting signal x[n] by an amount of bits as dictated by the decimal value of signal k. For instance, if signal k is a 4-bit signal, it can assume values in the range [0; 15], and the shifter circuit 124 can thus left-shift signal x[n] by a minimum of 0 bits (i.e., no shifting) to a maximum of 15 bits. Substantially, operation of the shifter circuit 124 corresponds to multiplying the decimal value of signal x[n] by a quantity equal to 2^{k} to compute the decimal value of signal s3[n], and it has to be noted that the operation of the shifter circuit 124 is substantially inverse with respect to the operation of the shifter circuit 110. The envelope detector circuit 120 includes a multiplexer circuit 126 that receives signal s3[n] from the left-shifter circuit 124 and signal s2[n] from the adder circuit 106 and is controlled by signal ctr. In particular, the multiplexer 126 passes to the memory element 108 the signal s3[n] if signal ctr is asserted (i.e., if x[n]>out[n]), and passes to the memory element 108 the signal s2[n] if signal ctr is de-asserted (i.e., if x[n]<out[n]).

Therefore, with the digital envelope detector structure exemplified in FIG. 12, if the input signal x[n] is greater than the current filter's output signal out[n], the value stored in the internal status register 108 of the IIR DC-track filter 100 is forced to x[n]*2^{k} (i.e., input data left-shifted by k bits), so that the next output value out[n] of the filter will be equal to the current input x[n](insofar as the left-shift operated by the shifter circuit 124 is reversed or compensated by the right-shift operated by the shifter circuit 110). As a result, the output signal out[n] of the digital envelope detector circuit 120 follows the input signal x[n] as long as the input is higher than the output, that is, as long as the input signal is rising or increasing: this phase substantially mimics the charge phase of capacitor C in the analog envelope detector of FIG. 8. On the other hand, if the input signal x[n] is lower than the current filter's output signal out[n], the envelope detector circuit 120 operates as a low-pass filter like a normal DC-track IIR filter 100: this phase substantially mimics the discharge phase of capacitor C in the analog envelope detector of FIG. 8.

In one or more embodiments, it is possible to control the speed of the “discharge” phase (when the control signal ctr is de-asserted) by changing the value of the shift-control signal k. As the value of signal k increases, the peak detector's output noise on constant level decreases; however, if the value of signal k is high, the “discharge” becomes slow and the output may not be able to follow the modulating signal. Purely by way of example, the value k=9 may represent a good trade-off, insofar as transitions are steep enough to follow the modulating signal and level noise does not affect the message decoding.

Thus, substantially, the envelope detector circuit 120 can be seen as including a memory element 108, a first digital processing circuitry arranged between the input terminal and the output terminal and including the memory element 108, and a second digital processing circuitry also arranged between the input terminal and the output terminal and including the memory element 108. The first digital processing circuitry includes a first processing portion arranged upstream of the memory element 108 (e.g., the optional sign extension circuit, the subtractor 104 and the adder 106 in the example of FIG. 12), and a second processing portion arranged downstream of the memory element 108 (e.g., the right-shifter circuit 110 and the optional truncation circuit 112 in the example of FIG. 12). The first digital processing circuitry is overall configured to apply low-pass filtering to the digital input signal x[n]. The second digital processing circuitry includes a first processing portion arranged upstream of the memory element 108 (e.g., the optional sign extension circuit and the left-shifter circuit 124 in the example of FIG. 12), and a second processing portion arranged downstream of the memory element 108 that is the same as the second processing portion of the first digital processing circuitry (e.g., it is physically shared with the first digital processing circuitry). The upstream portion of the second digital processing circuitry carries out the inverse operation of the downstream portion of the second (and first) digital processing circuitry, so that the second digital processing circuitry is overall configured to pass the digital input signal x[n] unaltered. In this respect, it will be noted that the second circuitry does not simply “bypass” the filter 100 within the envelope detector circuit 120, but rather is configured to process the digital input signal in a lossless manner with the upstream portion of the second digital processing circuitry (e.g., with the left-shifter circuit 124), store in the memory element 108 a value indicative of the lossless-processed digital input signal (e.g., the left-shifted value, that is the value of the digital input signal multiplied by 2^{k}), and process the output from the memory element 108 with the downstream portion of the second digital processing circuitry (e.g., with the right-shifter circuit 110 of the filter 100) so that the digital input signal is passed unaltered by the second digital processing circuitry to the output terminal of the filter 100 by compensating or reversing the operation of the upstream portion of the second digital processing circuitry (e.g., the shifter circuit 110). The first circuitry is enabled (via the comparator 122 and multiplexer 126) to produce the output signal out[n] in response to the input signal x[n] being lower than the output signal out[n], and the second processing circuitry is enabled (also via the comparator 122 and multiplexer 126) to produce the output signal out[n] in response to the input signal x[n] being higher than the output signal out[n]. In this way, the digital output signal out[n] is indicative of an envelope of the digital input signal x[n].

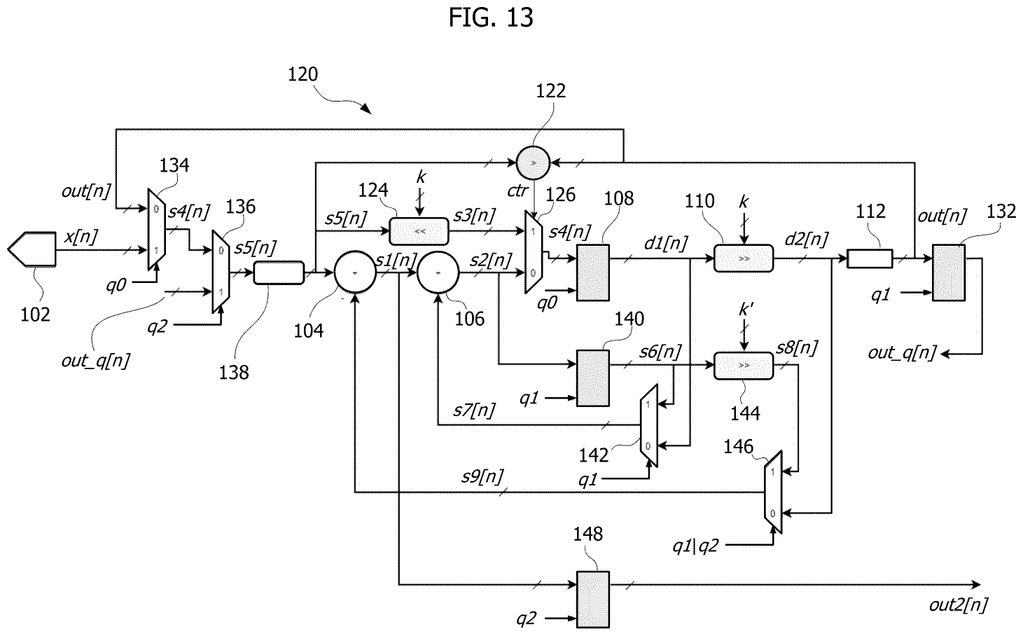

It is noted that the same filter as exemplified in FIG. 12 can be reused in order to remove the DC value from the output of the peak detector. To this end, a folded architecture may be used, which operates on three consecutive clock cycles, as exemplified in the circuit diagram of FIG. 13. In these embodiments, the digital envelope detector circuit 120 includes, in addition to the elements of the embodiments of FIG. 12 (i.e., 102, 104, 106, 108, 110, 112, 122, 124, 126), some more memory elements, multiplexers and a right-shifter arranged as described in the following.

In particular, it is now indicated in FIG. 13 that the memory element 108 of filter 100 receives, as enable signal, a timing signal q0. The circuit 120 includes a memory element 132 (e.g., a flip-flop, FF) that receives the output signal out[n] from the truncation circuit 112, stores the value of signal out[n] and passes it to its output to produce a signal out_q[n], as directed by a timing signal q1 that is provided to the enable terminal of flip-flop 132. The circuit 120 includes a multiplexer 134 that receives the input signal x[n] from the ADC 102 and the output signal out[n] from the truncation circuit 112 and is controlled by the timing signal q0. In particular, the multiplexer 134 passes to its output as signal s4[n] the signal x[n] if signal q0 is asserted, and passes to its output as signal s4[n] the signal out[n] if signal q0 is de-asserted. The circuit 120 includes a multiplexer 136 that receives the output signal out_q[n] from the memory element 132 and the signal s4[n] from the multiplexer 134 and is controlled by a timing signal q2. In particular, the multiplexer 136 passes to its output as signal s5[n] the signal out_q[n] if signal q2 is asserted, and passes to its output as signal s5[n] the signal s4[n] if signal q2 is de-asserted. The circuit 120 may include a sign extension block 138 that increases the number of bits of signal s5[n] before passing it to the subtractor circuit 104 (as previously discussed with reference to FIG. 10). Thus, compared to the embodiments of FIG. 12, in the embodiments of FIG. 13 signal s5[n] is passed to the subtractor 104, the comparator 122 and the left-shifter 124 instead of signal x[n], with signal s5[n] that can be equal to x[n], out[n] or out_q[n].

Furthermore, as exemplified in FIG. 13, the circuit 120 includes a memory element 140 (e.g., a flip-flop, FF) that receives the signal s2[n] from the adder circuit 106, stores the value of signal s2[n] and passes it to its output to produce a signal s6[n], as directed by the timing signal q1 that is provided to the enable terminal of flip-flop 140. The circuit 120 includes a multiplexer 142 that receives the signal s6[n] from the memory element 140 and the signal d1[n] from the memory element 108 and is controlled by the timing signal q1. In particular, the multiplexer 142 passes to its output as signal s7[n] the signal s6[n] if signal q1 is asserted, and passes to its output as signal s7[n] the signal d1[n] if signal q1 is de-asserted. Thus, compared to the embodiments of FIG. 12, in the embodiments of FIG. 13 either signal s6[n] or signal d1[n] is passed to the adder 106, depending on the value of the timing signal q1. The circuit 120 includes a right-shifter 144 that receives signal s6[n] from the memory element 140 and a shift-control signal k′ (e.g., a 4-bit signal), and produces a signal s8[n] by right-shifting signal s6[n] by an amount of bits as dictated by the decimal value of signal k′. For instance, if signal k′ is a 4-bit signal, it can assume values in the range [0; 15], and the shifter 144 can thus right-shift signal s6[n] by a minimum of 0 bits (i.e., no shifting) to a maximum of 15 bits. Substantially, operation of the shifter 144 corresponds to dividing the decimal value of signal s6[n] by a quantity equal to 2^{k′} to compute the decimal value of signal s8[n]. The circuit 120 includes a multiplexer 146 that receives the signal s8[n] from the shifter 144 and the signal d2[n] from the shifter 110 and is controlled by the logic-OR combination of timing signals q1 and q2 (indicated herein as q1|q2). In particular, the multiplexer 146 passes to its output as signal s9[n] the signal s8[n] if any one of signals q1 and q2 is asserted, and passes to its output as signal s9[n] the signal d2[n] if signals q1 and q2 are both de-asserted. Thus, compared to the embodiments of FIG. 12, in the embodiments of FIG. 13 either signal s8[n] or signal d2[n] is passed to the subtractor 104, depending on the value of the timing signals q1 and q2. Furthermore, the circuit 120 includes a memory element 148 (e.g., a flip-flop, FF) that receives the signal s1[n] from the subtractor circuit 104, stores the value of signal s1[n] and passes it to its output to produce a signal out2[n], as directed by the timing signal q2 that is provided to the enable terminal of flip-flop 148.

In three consecutive clock cycles, the timing signals q0, q1 and q2 are asserted sequentially (i.e., in the first clock cycle only signal q0 is asserted while signals q1 and q2 are de-asserted, in the second clock cycle only signal q1 is asserted while signals q0 and q2 are de-asserted, and in the third clock cycle only signal q2 is asserted while signals q0 and q1 are de-asserted). Therefore, the circuit of FIG. 13 operates as follows.

In the first clock cycle (q0=1, q1=0 and q2=0), the ADC 102 provides the input data x[n] and the first timing signal q0 is asserted to indicate that valid data is present at the input and is ready to be processed. In the configuration of the first clock cycle, the signal s5[n] that is passed to the subtractor 104 is equal to the input signal x[n], the signal s9[n] that is passed to the subtractor circuit 104 is equal to signal d2[n], and the signal s7[n] that is passed to the adder circuit 106 is equal to signal d1[n], just like during normal operation of the envelope detector circuit of FIG. 12. However, no output signal is provided, insofar as the signal out[n] is not yet loaded in the memory element 132: the state of the peak detector is just registered in the memory element 108.

In the second clock cycle (q0=0, q1=1 and q2=0), the computation of the peak detector is over, and the output signal out[n] from the truncation circuit 112 is fed back as signal s5[n] to the input of the subtractor circuit 104. The memory element 108 is now disabled so that it retains its previous value and is not affected by the computations carried out during the second clock cycle. The memory element 140 instead is enabled, so that the current value of signal s2[n] can be stored and used in the next clock cycle. The memory element 132 is also enabled, so that it captures the output from the truncation circuit 112 (computed on the value previously stored by the memory element 108).

In the third clock cycle (q0=0, q1=0 and q2=1), the computation of the DC value is over (and stored in the memory element 140). The value s6[n] stored in the memory element 140 is right-shifted by the shifter 144 to produce a new DC value s8[n], which is passed via the multiplexer 146 to the subtractor circuit 104 as signal s9[n]. The subtractor circuit 104 receives as signal s5[n] via the multiplexer 136 the value out_q[n] of the peak detector stored in the memory element 132, effectively implementing a high-pass filter behavior. The value of signal s1[n] computed by the subtractor circuit 104, which corresponds to the peak detector value without the DC component, is stored by the memory element 148 and provided as a further output signal out2[n].

In one or more embodiments, the output of the digital envelope detector circuit 120 (either out[n] or out2[n]) may be fed to a comparator (e.g., with hysteresis) for slicing, which can get rid of unwanted noise on the signal levels.

In one or more embodiments, the digital envelope detector circuit 120 may be implemented in a controller SoC (System-on-Chip) for a wireless power transmitter, in particular in an ASK demodulator of the SoC, in particular in the portion of the processing chain between the ADC that receives and digitizes the modulated signal, and the slicer section.

One or more embodiments may thus provide one or more of the following advantages:
low area of the digital envelope detector circuit, which is suitable for use in an ASK demodulator, compared to known solutions;
no need for band-pass filtering and/or rectification of the input signal prior to peak detection (insofar as the comparator 122 added to the structure of the IIR DC-track filter 100 make it operate as an envelope detector);
no need for dedicated high-pass filtering (insofar as the same DC-track filter can be used for both peak detection and high-pass filtering, in a folded architecture);
no need for convolution or multiplication hardware, insofar as the operations carried out by the circuit 120 include (only) shifts, addition/subtractions and comparisons.

Without prejudice to the underlying principles, the details and embodiments may vary, even significantly, with respect to what has been described by way of example only, without departing from the extent of protection.

The extent of protection is determined by the annexed claims.

What is claimed is:

1. A digital envelope detector circuit, comprising:
an input terminal configured to receive a digital input signal and an output terminal configured to produce a digital output signal;
a memory element;
first digital processing circuitry arranged between the input terminal and the output terminal and including the memory element, the first digital processing circuitry being configured to apply low-pass filtering to the digital input signal;
second digital processing circuitry arranged between the input terminal and the output terminal and including the memory element, the second digital processing circuitry being configured to process the digital input signal, store in the memory element a value indicative of the processed digital input signal, and process an output from the memory element so that the digital input signal is passed unaltered to the output terminal; and
a digital comparator circuit configured to compare the digital input signal to the digital output signal, assert a control signal in response to the digital input signal being higher than the digital output signal, and de-assert the control signal in response to the digital input signal being lower than the digital output signal;
wherein the first digital processing circuitry is configured to be enabled to produce the digital output signal in response to the control signal being de-asserted, and the second digital processing circuitry is configured to be enabled to produce the digital output signal in response to the control signal being asserted.

2. The digital envelope detector circuit of claim 1, wherein the processing applied by the second digital processing circuitry to the digital input signal is lossless, and wherein processing applied by the second digital processing circuitry to the value indicative of the processed digital input signal stored in the memory element is an inverse of the lossless processing.

3. The digital envelope detector circuit of claim 1, wherein:
the first digital processing circuitry comprises a respective first portion arranged between the input terminal and the memory element;
the second digital processing circuitry comprises a respective first portion arranged between the input terminal and the memory element;
the first digital processing circuitry and the second digital processing circuitry share a common second portion arranged between the memory element and the output terminal; and
the respective first portion of the second digital processing circuitry carries out an inverse operation of the common second portion.

4. The digital envelope detector circuit of claim 1, wherein the first digital processing circuitry comprises:
a subtractor circuit configured to subtract a first feedback signal from the digital input signal to produce a first intermediate signal;
an adder circuit configured to add together the first intermediate signal and a second feedback signal to produce a second intermediate signal;
the memory element configured to selectively receive the second intermediate signal, and to pass the second intermediate signal to the output of the memory element in response to a first enable signal being asserted to produce the second feedback signal; and
a right-shifter circuit configured to right-shift the second feedback signal by a first number of bits as indicated by a shift-control signal to produce the first feedback signal.

5. The digital envelope detector circuit of claim 4, wherein the first digital processing circuitry further comprises:
a sign extension circuit arranged between the input terminal and the subtractor circuit, and configured to increase a second number of bits of the digital input signal before passing it to the subtractor circuit; and
a truncation circuit arranged between the right-shifter circuit and the output terminal, and configured to truncate a third number of bits of the first feedback signal before passing it to the output terminal.

6. The digital envelope detector circuit of claim 4, wherein the second digital processing circuitry comprises:
a left-shifter circuit configured to left-shift the digital input signal by a fourth number of bits as indicated by the shift-control signal to produce a third intermediate signal;
the memory element configured to selectively receive the third intermediate signal, and to pass the third intermediate signal to the output of the memory element in response to the first enable signal being asserted to produce the second feedback signal; and
the right-shifter circuit.

7. The digital envelope detector circuit of claim 6, comprising a first multiplexer circuit configured to receive the second intermediate signal from the adder circuit and the third intermediate signal from the left-shifter circuit, and configured to pass to the input of the memory element the second intermediate signal in response to the control signal being de-asserted, or pass to the input of the memory element the third intermediate signal in response to the control signal being asserted.

8. The digital envelope detector circuit of claim 4, comprising:
a second memory element configured to receive the digital output signal, and to pass the digital output signal to an output of the second memory element in response to a second enable signal being asserted to produce a third feedback signal;
a second multiplexer circuit configured to receive the digital input signal and the digital output signal, and configured to produce a fourth intermediate signal at an output of the second multiplexer circuit by passing the digital input signal in response to the first enable signal being asserted, or passing the digital output signal in response to the first enable signal being de-asserted;
a third multiplexer circuit configured to receive the third feedback signal and the fourth intermediate signal, and configured to produce a fifth intermediate signal at an output of the third multiplexer circuit by passing the third feedback signal in response to a third enable signal being asserted, or passing the fourth intermediate signal in response to the third enable signal being de-asserted;
a third memory element configured to receive the second intermediate signal, and to pass the second intermediate signal to an output of the third memory element in response to the second enable signal being asserted to produce a sixth intermediate signal;
a fourth multiplexer circuit configured to receive the sixth intermediate signal and the second feedback signal, and configured to produce a seventh intermediate signal at an output of the fourth multiplexer circuit by passing the sixth intermediate signal in response to the second enable signal being asserted, or passing the second feedback signal in response to the second enable signal being de-asserted;
a second right-shifter circuit configured to right-shift the sixth intermediate signal by a fifth number of bits as indicated by a further shift-control signal to produce an eighth intermediate signal;
a fifth multiplexer circuit configured to receive the eighth intermediate signal and the first feedback signal, and configured to produce a ninth intermediate signal at an output of the fifth multiplexer circuit by passing the eighth intermediate signal in response to any of the second enable signal and the third enable signal being asserted, or passing the first feedback signal in response to the second enable signal and the third enable signal being both de-asserted;
a fourth memory element configured to receive the first intermediate signal, and to pass the first intermediate signal to an output of the fourth memory element in response to the third enable signal being asserted to produce a further digital output signal;
wherein the subtractor circuit is configured to subtract the ninth intermediate signal from the fifth intermediate signal to produce the first intermediate signal; and
wherein the adder circuit is configured to add together the first intermediate signal and the seventh intermediate signal to produce the second intermediate signal.

9. The digital envelope detector circuit of claim 8, wherein the first, second, and third enable signals are asserted sequentially, one at a time, in three consecutive clock cycles.

10. A system-on-chip, comprising:
an analog-to-digital converter configured to receive an analog amplitude-modulated signal and convert it to produce a digital input signal;
a digital envelope detector circuit comprising:
an input terminal configured to receive the digital input signal from the analog-to-digital converter, and an output terminal configured to produce a digital output signal;
a memory element;
first digital processing circuitry arranged between the input terminal and the output terminal and including the memory element, the first digital processing circuitry being configured to apply low-pass filtering to the digital input signal;
second digital processing circuitry arranged between the input terminal and the output terminal and including the memory element, the second digital processing circuitry being configured to process the digital input signal, store in the memory element a value indicative of the processed digital input signal, and process an output from the memory element so that the digital input signal is passed unaltered to the output terminal; and
a digital comparator circuit configured to compare the digital input signal to the digital output signal, assert a control signal in response to the digital input signal being higher than the digital output signal, and de-assert the control signal in response to the digital input signal being lower than the digital output signal;
wherein the first digital processing circuitry is configured to be enabled to produce the digital output signal in response to the control signal being de-asserted, and the second digital processing circuitry is configured to be enabled to produce the digital output signal in response to the control signal being asserted; and
an ASK demodulator circuit configured to decode the digital output signal produced by the digital envelope detector circuit.

11. The system-on-chip of claim 10, wherein the processing applied by the second digital processing circuitry to the digital input signal is lossless, and wherein processing applied by the second digital processing circuitry to the value indicative of the processed digital input signal stored in the memory element is an inverse of the lossless processing.

12. The system-on-chip of claim 10, wherein:
the first digital processing circuitry comprises a respective first portion arranged between the input terminal and the memory element;
the second digital processing circuitry comprises a respective first portion arranged between the input terminal and the memory element;
the first digital processing circuitry and the second digital processing circuitry share a common second portion arranged between the memory element and the output terminal; and
the respective first portion of the second digital processing circuitry carries out an inverse operation of the common second portion.

13. The system-on-chip of claim 10, wherein the first digital processing circuitry comprises:
a subtractor circuit configured to subtract a first feedback signal from the digital input signal to produce a first intermediate signal;
an adder circuit configured to add together the first intermediate signal and a second feedback signal to produce a second intermediate signal;
the memory element configured to selectively receive the second intermediate signal, and to pass the second intermediate signal to the output of the memory element in response to a first enable signal being asserted to produce the second feedback signal; and
a right-shifter circuit configured to right-shift the second feedback signal by a first number of bits as indicated by a shift-control signal to produce the first feedback signal.

14. The system-on-chip of claim 13, wherein the first digital processing circuitry further comprises:
a sign extension circuit arranged between the input terminal and the subtractor circuit, and configured to increase a second number of bits of the digital input signal before passing it to the subtractor circuit; and
a truncation circuit arranged between the right-shifter circuit and the output terminal, and configured to truncate a third number of bits of the first feedback signal before passing it to the output terminal.

15. The system-on-chip of claim 13, wherein the second digital processing circuitry comprises:
a left-shifter circuit configured to left-shift the digital input signal by a fourth number of bits as indicated by the shift-control signal to produce a third intermediate signal;
the memory element configured to selectively receive the third intermediate signal, and to pass the third intermediate signal to the output of the memory element in response to the first enable signal being asserted to produce the second feedback signal; and
the right-shifter circuit.

16. The system-on-chip of claim 15, comprising a first multiplexer circuit configured to receive the second intermediate signal from the adder circuit and the third intermediate signal from the left-shifter circuit, and configured to pass to the input of the memory element the second intermediate signal in response to the control signal being de-asserted, or pass to the input of the memory element the third intermediate signal in response to the control signal being asserted.

17. The system-on-chip of claim 13, comprising:
a second memory element configured to receive the digital output signal, and to pass the digital output signal to an output of the second memory element in response to a second enable signal being asserted to produce a third feedback signal;
a second multiplexer circuit configured to receive the digital input signal and the digital output signal, and configured to produce a fourth intermediate signal at an output of the second multiplexer circuit by passing the digital input signal in response to the first enable signal being asserted, or passing the digital output signal in response to the first enable signal being de-asserted;
a third multiplexer circuit configured to receive the third feedback signal and the fourth intermediate signal, and configured to produce a fifth intermediate signal at an output of the third multiplexer circuit by passing the third feedback signal in response to a third enable signal being asserted, or passing the fourth intermediate signal in response to the third enable signal being de-asserted;
a third memory element configured to receive the second intermediate signal, and to pass the second intermediate signal to an output of the third memory element in response to the second enable signal being asserted to produce a sixth intermediate signal;
a fourth multiplexer circuit configured to receive the sixth intermediate signal and the second feedback signal, and configured to produce a seventh intermediate signal at an output of the fourth multiplexer circuit by passing the sixth intermediate signal in response to the second enable signal being asserted, or passing the second feedback signal in response to the second enable signal being de-asserted;
a second right-shifter circuit configured to right-shift the sixth intermediate signal by a fifth number of bits as indicated by a further shift-control signal to produce an eighth intermediate signal;
a fifth multiplexer circuit configured to receive the eighth intermediate signal and the first feedback signal, and configured to produce a ninth intermediate signal at an output of the fifth multiplexer circuit by passing the eighth intermediate signal in response to any of the second enable signal and the third enable signal being asserted, or passing the first feedback signal in response to the second enable signal and the third enable signal being both de-asserted;
a fourth memory element configured to receive the first intermediate signal, and to pass the first intermediate signal to an output of the fourth memory element in response to the third enable signal being asserted to produce a further digital output signal;
wherein the subtractor circuit is configured to subtract the ninth intermediate signal from the fifth intermediate signal to produce the first intermediate signal; and
wherein the adder circuit is configured to add together the first intermediate signal and the seventh intermediate signal to produce the second intermediate signal.

18. A method of operating a digital envelope detector circuit, the method comprising:
receiving a digital input signal at an input terminal;
applying, by first digital processing circuitry, low-pass filtering to the digital input signal;
processing, by second digital processing circuitry, the digital input signal;
storing, by the second digital processing circuitry, in a memory element a value indicative of the processed digital input signal;
processing, by the second digital processing circuitry, an output from the memory element so that the digital input signal is passed unaltered to an output terminal;
first comparing, by a digital comparator circuit, the digital input signal to a digital output signal produced at the output terminal;
asserting, by the digital comparator circuit, a control signal in response to the digital input signal being higher than the digital output signal;
enabling the first digital processing circuitry to produce the digital output signal in response to the control signal being de-asserted;
second comparing, by the digital comparator circuit, the digital input signal to the digital output signal;
de-asserting, by the digital comparator circuit, the control signal in response to the digital input signal being lower than the digital output signal; and
enabling the second digital processing circuitry to produce the digital output signal in response to the control signal being asserted.

19. The method of claim 18, further comprising:
subtracting, by a subtractor circuit of the first digital processing circuitry, a first feedback signal from the digital input signal to produce a first intermediate signal;
adding together, by an adder circuit of the first digital processing circuitry, the first intermediate signal and a second feedback signal to produce a second intermediate signal;
selectively receiving, by the memory element, the second intermediate signal, and passing the second intermediate signal to the output of the memory element in response to a first enable signal being asserted to produce the second feedback signal; and
right-shifting, by a right-shifter circuit of the first digital processing circuitry, the second feedback signal by a first number of bits as indicated by a shift-control signal to produce the first feedback signal.

20. The method of claim 19, further comprising:
increasing, by a sign extension circuit of the first digital processing circuitry, a second number of bits of the digital input signal before passing it to the subtractor circuit; and
truncating, by a truncation circuit of the first digital processing circuitry, a third number of bits of the first feedback signal before passing it to the output terminal.

21. The method of claim 19, further comprising:
left-shifting, by a left-shifter circuit of the second digital processing circuitry, the digital input signal by a fourth number of bits as indicated by the shift-control signal to produce a third intermediate signal; and
selectively receiving, by the memory element, the third intermediate signal, and passing the third intermediate signal to the output of the memory element in response to the first enable signal being asserted to produce the second feedback signal.

22. The method of claim 21, further comprising, by a first multiplexer circuit:
receiving the second intermediate signal from the adder circuit and the third intermediate signal from the left-shifter circuit; and
passing to the input of the memory element the second intermediate signal in response to the control signal being de-asserted; or
passing to the input of the memory element the third intermediate signal in response to the control signal being asserted.

23. The method of claim 19, further comprising:
receiving, by a second memory element, the digital output signal, and passing the digital output signal to an output of the second memory element in response to a second enable signal being asserted to produce a third feedback signal; and
receiving, by a second multiplexer circuit, the digital input signal and the digital output signal, and producing a fourth intermediate signal at an output of the second multiplexer circuit by:
passing the digital input signal in response to the first enable signal being asserted; or
passing the digital output signal in response to the first enable signal being de-asserted;
receiving, by a third multiplexer circuit, the third feedback signal and the fourth intermediate signal, and producing a fifth intermediate signal at an output of the third multiplexer circuit by:
passing the third feedback signal in response to a third enable signal being asserted; or
passing the fourth intermediate signal in response to the third enable signal being de-asserted;
receiving, by a third memory element, the second intermediate signal, and passing the second intermediate signal to an output of the third memory element in response to the second enable signal being asserted to produce a sixth intermediate signal;
receiving, by a fourth multiplexer circuit, the sixth intermediate signal and the second feedback signal, and producing a seventh intermediate signal at an output of the fourth multiplexer circuit by:
passing the sixth intermediate signal in response to the second enable signal being asserted; or
passing the second feedback signal in response to the second enable signal being de-asserted;
right-shifting, by a second right-shifter circuit, the sixth intermediate signal by a fifth number of bits as indicated by a further shift-control signal to produce an eighth intermediate signal;
receiving, by a fifth multiplexer circuit, the eighth intermediate signal and the first feedback signal, and producing a ninth intermediate signal at an output of the fifth multiplexer circuit by:
passing the eighth intermediate signal in response to any of the second enable signal and the third enable signal being asserted; or
passing the first feedback signal in response to the second enable signal and the third enable signal being both de-asserted;
receiving, by a fourth memory element, the first intermediate signal, and passing the first intermediate signal to an output of the fourth memory element in response to the third enable signal being asserted to produce a further digital output signal;
subtracting, by the subtractor circuit, the ninth intermediate signal from the fifth intermediate signal to produce the first intermediate signal;
adding together, by the adder circuit the first intermediate signal and the seventh intermediate signal to produce the second intermediate signal; and
asserting sequentially, the first, second, and third enable signals, one at a time, in three consecutive clock cycles.
